(19) United States
(12) Patent Application Publication
(10) Pub. No.: US 2026/0312512 A1
(43) Pub. Date: Oct. 8, 2026

(54) POWER CONVERSION APPARATUS AND OUTDOOR UNIT OF AIR CONDITIONER

(71) Applicant: Mitsubishi Electric Corporation, Tokyo (JP)

(72) Inventors: Takahiko KOBAYASHI, Tokyo (JP); Hiroki SUZUKI, Tokyo (JP); Fumiaki SHIBATA, Tokyo (JP)

(21) Appl. No.: 19/152,881

(22) PCT Filed: Feb. 28, 2023
(86) PCT No.: PCT/JP2023/007356

§ 371 Date: Jul. 31, 2025

(51) Int. Cl. H02M 7/53; F24F 11/88; G01R 21/06; H02M 7/06; H02P 27/00

(52) U.S. Cl. CPC H02M 7/53; F24F 11/88; G01R 21/06; H02M 7/06; H02P 27/00

(57) ABSTRACT

A power conversion apparatus includes: a converter that rectifies an alternating-current voltage supplied from an alternating-current power source; an inverter that converts the rectified voltage into an alternating-current voltage; a first voltage detection unit that detects the voltage input to the inverter; a zero-crossing detection unit that detects at least one voltage zero-crossing point on power lines; a current detection unit that detects a current value of the alternating-current power; a power source voltage reconstruction unit that reconstructs information on the basis of the detected voltage zero-crossing point and the voltage detected by the first voltage detection unit, the information being related to alternating-current quantities of the alternating-current voltage; and a power calculation unit that calculates input power from the alternating-current power source on the basis of the information and the current value of the alternating-current power.

### CROSS-REFERENCE TO RELATED APPLICATION

This application is a U.S. national stage application of PCT/JP 2023/007356 filed Feb. 28, 2023, the contents of which are incorporated herein by reference.

### FIELD

The present disclosure relates to a power conversion apparatus that rectifies alternating-current power supplied from a commercial power source and then performs conversion into alternating-current power for output. The present disclosure also relates to an outdoor unit of an air conditioner that includes the power conversion apparatus.

### BACKGROUND

In a power conversion apparatus that rectifies alternating-current power supplied from a commercial power source and then performs conversion into alternating-current power for output, as disclosed in Patent Literature 1, an amplitude value of a phase voltage of a power source voltage is determined from a detected bus voltage value, and the input power is determined on the basis of the determined amplitude of the phase voltage and an active current component.

### PATENT LITERATURE

Patent Literature 1: Japanese Patent Application Laid-open No. 2009-089469

The power conversion apparatus disclosed in Patent Literature 1 determines the input power on the basis of the amplitude value of the power source and the active current, not obtaining information related to alternating-current quantities of the power source voltage. Therefore, accuracy of the input power is reduced. Implementing a circuit that detects the alternating-current quantities of the power source voltage increases substrate size and component costs, presenting a problem.

### SUMMARY

The present disclosure has been made in view of the above, and an object of the present disclosure is to obtain a power conversion apparatus capable of estimating input power with higher accuracy while restraining increases in substrate size and component costs.

To solve the above problem and achieve the object, a power conversion apparatus according to the present disclosure comprises: a converter to rectify alternating-current power supplied from an alternating-current power source; a main-circuit capacitor to smooth the power rectified by the converter; a reactor provided between the converter and the main-circuit capacitor; an inverter to convert the power rectified by the converter into alternating-current power for output to a motor; and a drive signal generation unit to generate drive signals for driving the motor, and output the drive signals to the inverter. The power conversion apparatus further comprises: a first voltage detection unit to detect voltage at an input part of the inverter; a zero-crossing detection unit to detect at least one voltage zero-crossing point on power lines interconnecting the alternating-current power source and the converter; a current detection unit to detect a current value of alternating-current power supplied from the alternating-current power source; a power source voltage reconstruction unit to reconstruct information on a basis of the voltage zero-crossing point detected by the zero-crossing detection unit and the voltage detected at the input part of the inverter by the first voltage detection unit, the information being related to alternating-current quantities of alternating-current power supplied from the alternating-current power source; and a power calculation unit to calculate input power from the alternating-current power source on a basis of the information related to the alternating-current quantities and reconstructed by the power source voltage reconstruction unit and the current value of the alternating-current power detected by the current detection unit.

The power conversion apparatus according to the present disclosure has an effect of estimating the input power with higher accuracy while restraining increases in substrate size and component costs.

### BRIEF DESCRIPTION OF DRAWINGS

FIG. 1 is a diagram illustrating a configuration of a power conversion apparatus according to a first embodiment.

FIG. 2 is a diagram illustrating an exemplary configuration of hardware that implements a control unit of the power conversion apparatus according to the first embodiment.

FIG. 3 is a diagram illustrating an exemplary relationship between a power source voltage waveform and a detection signal in the power conversion apparatus according to the first embodiment.

FIG. 4 is a diagram illustrating a configuration of a power conversion apparatus according to a second embodiment.

FIG. 5 is a diagram illustrating an exemplary relationship between a power source voltage waveform and a detection signal in the power conversion apparatus according to the second embodiment.

FIG. 6 is a diagram illustrating a configuration of a power conversion apparatus according to a third embodiment.

FIG. 7 is a diagram illustrating a power source voltage and an output voltage of a rectifier circuit in the power conversion apparatus according to the third embodiment in the presence of an imbalance in a three-phase power source.

FIG. 8 is a diagram illustrating a configuration of a power conversion apparatus according to a fourth embodiment.

FIG. 9 is a diagram illustrating a configuration of a power conversion apparatus according to a fifth embodiment.

FIG. 10 is a diagram illustrating a configuration of a power conversion apparatus according to a sixth embodiment.

FIG. 11 is a diagram illustrating a configuration of an outdoor unit of an air conditioner according to a seventh embodiment.

FIG. 12 is a diagram illustrating a configuration of a power conversion apparatus included in the outdoor unit of the air conditioner according to the seventh embodiment.

### DETAILED DESCRIPTION

With reference to the drawings, a detailed description is hereinafter provided of power conversion apparatuses and an outdoor unit of an air conditioner according to embodiments.

### First Embodiment

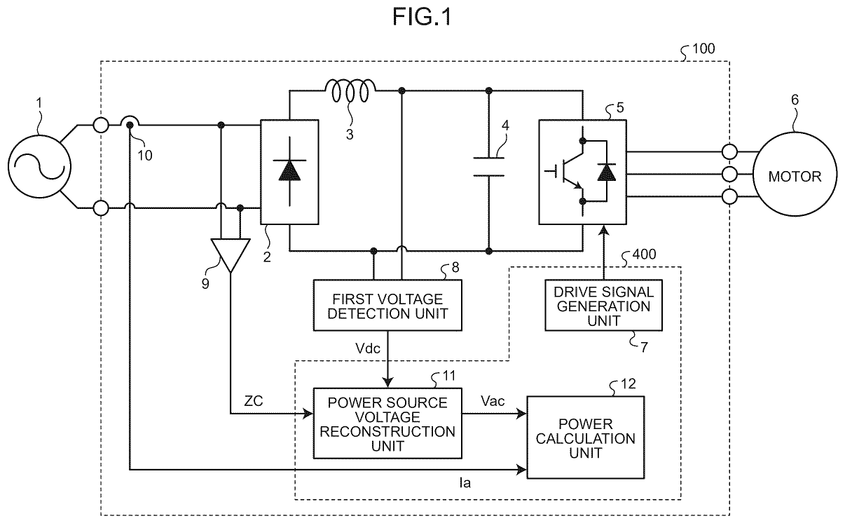

FIG. 1 is a diagram illustrating a configuration of a power conversion apparatus according to a first embodiment. The power conversion apparatus 100 according to the first embodiment includes a converter 2, a reactor 3, a main-circuit capacitor 4, an inverter 5, a drive signal generation unit 7, a first voltage detection unit 8, a zero-crossing detection unit 9, and a current detection unit 10. The converter 2 rectifies an alternating-current voltage supplied from an alternating-current power source 1. The reactor 3 is provided between the converter 2 and the main-circuit capacitor 4. The main-circuit capacitor 4 smooths the rectified voltage. The inverter 5 converts the rectified and smoothed voltage into an alternating-current voltage for output to a motor 6. The drive signal generation unit 7 generates and transmits drive signals to the inverter 5 in order to drive the motor 6. The first voltage detection unit 8 detects the voltage Vdc at an input part of the inverter 5. The zero-crossing detection unit 9 detects at least one phase-to-phase voltage zero-crossing point. The current detection unit 10 detects a current value of alternating-current power. Either an electrolytic capacitor or a film capacitor may be used as the main-circuit capacitor 4.

The drive signal generation unit 7 generates the drive signals for controlling power conversion operation of the inverter 5 on the basis of externally input voltage commands (not illustrated) and transmits the drive signals to the inverter 5. Using a publicly known and general method, the drive signal generation unit 7 generates the drive signals. The output voltage from the inverter 5 to the motor 6 depends on the voltage Vdc at the input part of the inverter 5; therefore, the drive signals may be generated on the basis of information of the voltage Vdc, which is detected at the input part of the inverter 5 by the first voltage detection unit 8.

The power conversion apparatus 100 also includes a power source voltage reconstruction unit 11 and a power calculation unit 12. On the basis of the voltage zero-crossing point detected by the zero-crossing detection unit 9 and a voltage detection value detected by the first voltage detection unit 8, the power source voltage reconstruction unit 11 reconstructs information related to alternating-current quantities of the power source voltage. The power calculation unit 12 calculates the input power on the basis of a reconstructed power source voltage and the current detection value detected by the current detection unit 10. Here, the term “alternating-current quantities” refers to values that represent waveform characteristics of the alternating-current voltage, including the alternating-current voltage's amplitude and phase.

The zero-crossing detection unit 9 detects when the power source voltage supplied from the alternating-current power source 1 passes through the voltage zero-crossing point and outputs a detection signal ZC to the power source voltage reconstruction unit 11.

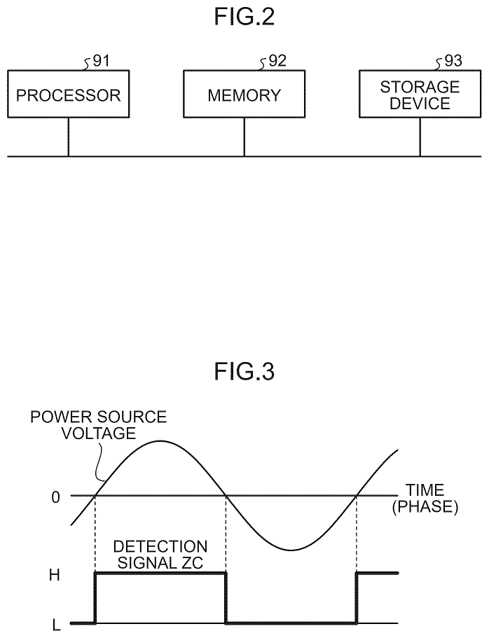

The drive signal generation unit 7, the power source voltage reconstruction unit 11, and the power calculation unit 12 are provided in a control unit 400. FIG. 2 is a diagram illustrating an exemplary configuration of hardware that implements the control unit of the power conversion apparatus according to the first embodiment. The control unit 400 is implemented using a processor 91 that executes various processes, a memory 92 serving as a main memory, and a storage device 93 that stores information.

The processor 91 may be an operation means, such as an arithmetic unit, a microprocessor, a microcomputer, a central processing unit (CPU), or a digital signal processor (DSP). For the memory 92, a nonvolatile or volatile semiconductor memory, such as a random access memory (RAM), a read only memory (ROM), a flash memory, an erasable programmable read only memory (EPROM), or an electrically erasable programmable read only memory (EEPROM) (registered trademark), can be used. The storage device 93 stores a program for executing a capacitor loading reduction control process. The processor 91 reads programs stored in the storage device 93 into the memory 92 to execute the programs. The processor 91 reads the programs stored in the storage device 93 into the memory 92 and executes the programs, thus implementing the functions of the control unit 400.

The drive signal generation unit 7, the power source voltage reconstruction unit 11, and the power calculation unit 12 may be implemented by a common function of the processor 91 or may be implemented respectively by separate functions of the processor 91.

FIG. 3 is a diagram illustrating an exemplary relationship between a power source voltage waveform and the detection signal in the power conversion apparatus according to the first embodiment. The zero-crossing detection unit 9 outputs the detection signal ZC at a high level to the power source voltage reconstruction unit 11 when the power source voltage waveform passes through the voltage zero-crossing point and outputs the detection signal ZC at a low level to the power source voltage reconstruction unit 11 when the power source voltage waveform passes through a subsequent voltage zero-crossing point. The zero-crossing detection unit 9 then outputs the detection signal ZC at the high level again when the power source voltage waveform passes through a subsequent voltage zero point, thus repeatedly switching the signal between the high and low output levels each time the power source voltage passes through a voltage zero-crossing point.

A mode illustrated in FIG. 3 is such that the detection signal ZC is output at the high level while the power source voltage is positive and at the low level while the power source voltage is negative; however, this example is not limiting. The mode may be such that the detection signal ZC is output at the low level while the power source voltage is positive and at the high level while the power source voltage is negative.

The power source voltage reconstruction unit 11 determines the phase and the amplitude of the power source voltage and reconstructs the power source voltage waveform on the basis of the determined phase and amplitude. In other words, the power source voltage reconstruction unit 11 reconstructs the phase, the amplitude, and the power source voltage waveform.

First, a description of the phase reconstruction is provided. The power source voltage reconstruction unit 11 expresses the power source voltage phase by defining the timing when the detection signal ZC changes from the low level to the high level as 0 [rad], the timing when the detection signal ZC changes from the high level to the low level as π [rad], and one cycle as 2π [rad]. The power source voltage reconstruction unit 11 counts time t [s] that elapses from when the power source voltage passes through the voltage zero-crossing point, calculates the power source voltage phase from the elapsed time, and generates a sinusoidal signal X synchronized with the calculated power source voltage phase.

The power source voltage reconstruction unit 11 determines the power source voltage phase, using the relation θac=∩ac·t, where the power source voltage phase is θac [rad], a power source voltage frequency is ωac [rad/s], and the time elapsed from when the detection signal ZC changes from the low level to the high level is t [s]. On the basis of power source specifications, the power source voltage frequency is generally constant. However, if the power supply is unstable, frequency fluctuations may occur, in which case the power source voltage will not be supplied at a uniform power source voltage frequency ωac. Accordingly, the power source voltage reconstruction unit 11 may count time from when the power source voltage passes through the voltage zero-crossing point to the next such timing and appropriately correct the power source voltage frequency ωac. On the basis of the power source voltage phase θac thus calculated, the power source voltage reconstruction unit 11 generates the sinusoidal signal X=sin(θac).

Next, a description of the amplitude reconstruction is provided. Based on the assumption that a single-phase full-wave rectifier circuit is used for the converter 2 and that a voltage drop in the reactor 3 is small, a relation between an average value of the voltage Vdc, which is the voltage detected at the input part of the inverter 5 by the first voltage detection unit 8, and the amplitude Vamp of the power source voltage is given by Vamp=(1π/2)Vdc.

If capacitance of the main-circuit capacitor 4 is small, leading to a significant pulsation in the detection value of Vdc, the configuration may include a filter that, in the form of hardware or software, smooths the pulsation in the detection value. Software that performs a filtering operation such as an averaging operation can be given as an example of the software that implements the filter for smoothing the pulsation in the detection value.

In the example described above, the single-phase full-wave rectifier circuit is used for the converter 2; however, a rectifier circuit other than a full-wave rectifier circuit, a power factor correction circuit, or a boost circuit may be used for the converter 2. In that case, a computing formula that is used in the amplitude reconstruction process differs from the above formula; however, the amplitude can be reconstructed in a similar manner.

Next, a description of the reconstruction of the power source voltage waveform is provided. The power source voltage reconstruction unit 11 calculates the power source voltage Vac based on the sinusoidal signal X and the result of reconstructing the amplitude Vamp, using Vac=(π/2)Vdc·sin(θac), thus reconstructing the power source voltage waveform.

The power calculation unit 12 calculates the input power P on the basis of the current value of the alternating-current power that is detected by the current detection unit 10 and the reconstructed power source voltage Vac. The power calculation unit 12 calculates the input power P using P=Vac·Ia, where the instantaneous current value Ia of the single-phase alternating-current power is used.

The power conversion apparatus 100 according to the first embodiment can detect the information that is related to the alternating-current quantities of the power source voltage and which is required for calculating the input power to the power conversion apparatus 100, eliminating the need for a detection means for direct detection, such as a power source voltage sensor. Specifically, the zero-crossing detection unit 9 is a simple circuit that includes a substrate-mounted electronic component, has a small substrate footprint, and can be configured at low cost. Therefore, the power conversion apparatus 100 can be implemented in a smaller size and at a lower cost than a power conversion apparatus configured to directly detect the power source voltage by means of the power source voltage sensor.

The power conversion apparatus 100 illustrated in FIG. 1 has the reactor 3 disposed as a direct-current reactor on a bus line; however, the power conversion apparatus 100 may be configured with an alternating-current reactor provided on power lines between the alternating-current power source 1 and the converter 2.

### Second Embodiment

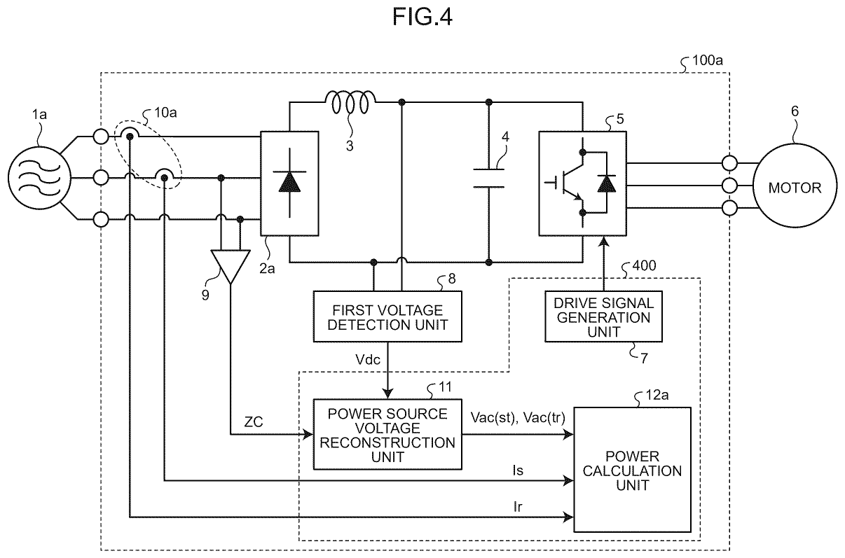

FIG. 4 is a diagram illustrating a configuration of a power conversion apparatus according to a second embodiment. The power conversion apparatus 100a according to the second embodiment is supplied with power from a three-phase alternating-current power source 1a. The three-phase alternating-current power source 1a and a converter 2a are connected by R-phase, T-phase, and S-phase power lines. A current detection unit 10a detects current values of the R phase and the S phase. The instantaneous current value Ir of the R phase and the instantaneous current value Is of the S phase are input to a power calculation unit 12a.

The zero-crossing detection unit 9 detects at least one phase-to-phase voltage zero-crossing point. The zero-crossing detection unit 9 is defined as detecting a zero-crossing point of line voltage Vst between S-phase voltage Vs and T-phase voltage Vt and a zero-crossing point of line voltage Vtr between R-phase voltage Vr and the T-phase voltage Vt. The following description is made as to the zero-crossing detection unit 9 detecting the zero-crossing point of the line voltage Vst between the S-phase voltage Vs and the T-phase voltage Vt among the R, S, and T phases of the power source. However, the same is true of the detection for the line voltage Vtr between the R-phase voltage Vr and the T-phase voltage Vt.

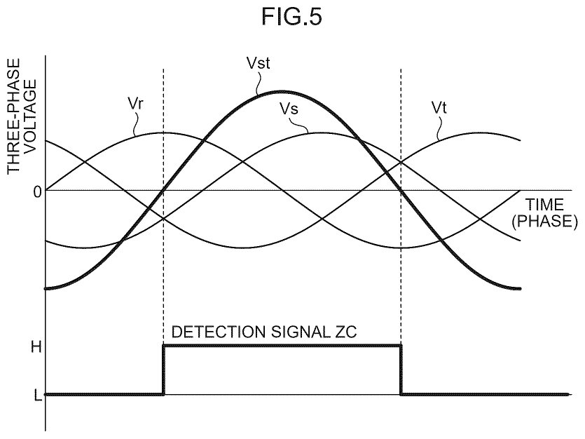

FIG. 5 is a diagram illustrating an exemplary relationship between a power source voltage waveform and a detection signal in the power conversion apparatus according to the second embodiment. The zero-crossing detection unit 9 outputs the detection signal ZC at a high level to the power source voltage reconstruction unit 11 when a voltage waveform of the line voltage Vst between the S phase and the T phase passes through the voltage zero-crossing point and outputs the detection signal ZC at a low level to the power source voltage reconstruction unit 11 when the voltage waveform passes through a subsequent voltage zero point. The zero-crossing detection unit 9 then outputs the detection signal ZC at the high level again when the voltage waveform passes through a subsequent voltage zero point, thus repeatedly switching the signal between the high and low output levels each time the voltage waveform of the line voltage Vst between the S phase and the T phase passes through a voltage zero-crossing point.

A mode illustrated in FIG. 5 is such that the detection signal ZC is output at the high level while the voltage waveform of the line voltage Vst between the S phase and the T phase is positive and at the low level while the voltage waveform of the line voltage Vst between the S phase and the T phase is negative; however, this example is not limiting. The mode may be such that the detection signal ZC is output at the low level while the voltage waveform of the line voltage Vst between the S phase and the T phase is positive and at the high level while the voltage waveform is negative.

Based on the assumption that a three-phase full-wave rectifier circuit is used for the converter 2a and that a voltage drop in the reactor 3 is small, the power source voltage reconstruction unit 11 calculates the amplitude Vamp of the power source voltage through Vamp=(π/3) Vdc, using an average value of the voltage Vdc, which is the voltage detected at the input part of the inverter 5 by the first voltage detection unit 8. For the sake of calculating input power using Blondel's theorem, which is described later, the power source voltage reconstruction unit 11 reconstructs the line voltage Vac(st) between the S phase and T phase and the line voltage Vac(tr) between the T phase and the R phase. The input power may be calculated using a calculation method other than Blondel's theorem.

The power calculation unit 12a calculates the input power P using P=Vac(st)·Ir+Vac(tr)·Is, where the instantaneous current value Ir of the R phase and the instantaneous current value Is of the S phase are used.

In the case described above, the current detection unit 10a detects the currents of the two phases, and the zero-crossing detection unit 9 detects the single zero-crossing point. However, detecting currents an increased number of phases or an increased number of zero-crossing points enables variations in each of the phases to be factored into the power calculation. Furthermore, the current values of the alternating-current power and the voltage zero-crossing point of the alternating-current voltage may be detected at plural points without being limited to the detections in this embodiment, and reconstructions may be carried out accordingly for the input power to be calculated. For the three-phase power source, the phases to be detected are not limited to the previously mentioned selected phases.

The power conversion apparatus 100a according to the second embodiment can detect information that is related to alternating-current quantities of the power source voltage of the three-phase alternating-current power source 1a and which is required for calculating the input power to the power conversion apparatus 100a, eliminating the need for a detection means for direct detection, such as a power source voltage sensor.

### Third Embodiment

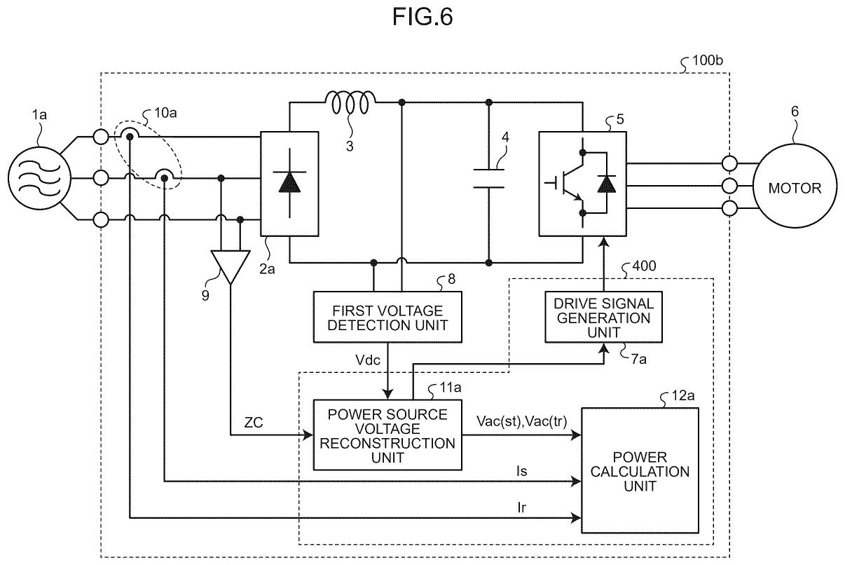

FIG. 6 is a diagram illustrating a configuration of a power conversion apparatus according to a third embodiment. In the power conversion apparatus 100b according to the third embodiment, a power source voltage reconstruction unit 11a determines whether or not a voltage imbalance has occurred among the R-phase, S-phase, and T-phase voltages supplied from the three-phase alternating-current power source 1a. Upon determining that the voltage imbalance has occurred, the power source voltage reconstruction unit 11a notifies a drive signal generation unit 7a of the occurrence of the voltage imbalance. When notified of the occurrence of the voltage imbalance, the drive signal generation unit 7a generates drive signals that reduce the output of the inverter 5. The power conversion apparatus 100b is otherwise similar to the power conversion apparatus 100a according to the second embodiment.

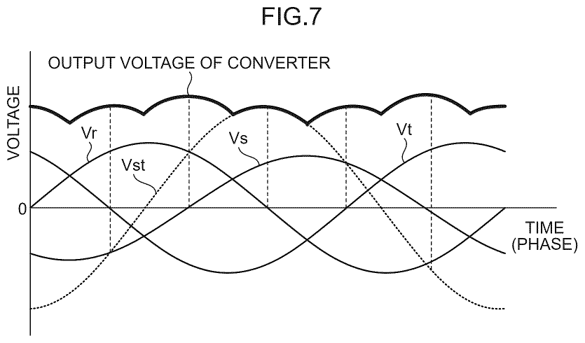

FIG. 7 is a diagram illustrating a power source voltage and an output voltage of a rectifier circuit in the power conversion apparatus according to the third embodiment in the presence of an imbalance in the three-phase power source. Vr represents the R-phase voltage, Vs represents the S-phase voltage, and Vt represents the T-phase voltage. In the example of FIG. 7, the S phase is smaller in amplitude than the R phase and the T phase. When the converter 2a is a three-phase full-wave rectifier circuit, as illustrated in FIG. 7, a voltage difference between a maximum value and a minimum value among the voltages of the phases becomes the output voltage of the converter 2a. The minimum voltage value here refers to the voltage value with a negative sign that is the largest as an absolute value. As illustrated in FIG. 7, local maxima appear in the output voltage of the converter 2a at intervals of ⅙ of a power supply cycle. If the three-phase power source is balanced, the local maxima will be the same. However, in the example illustrated in FIG. 7, the amplitude of the S phase is small compared with the amplitudes of the R phase and the T phase, causing the voltage imbalance that results in fluctuations in the local maximum.

If the line voltage Vst between the S phase and the T phase is reconstructed by the power source voltage reconstruction unit 11a, as illustrated in FIG. 7, the above-mentioned local maxima appear when the phases [rad] of Vst are π/6, π/2, 5π/6, 7π/6, 3π/2, and 11π/6. The first voltage detection unit 8 detects instantaneous voltage values where those phases match phases of reconstructed values Vac(rs) of the line voltage Vrs between the R phase and the S phase. When the voltage detected at each instance fluctuates, it is determined that the voltage imbalance has occurred. In other words, it is determined that the voltage imbalance has occurred when the difference between the maximum and minimum values among the local maxima detected by the first voltage detection unit 8 exceeds a predetermined value.

Determining whether a voltage imbalance has occurred may be based on local minima that similarly appear at intervals of ⅙ of the power supply cycle when the phase [rad] of Vst is 0, π/3, 2π/3, π, 4π/3, and 5π/3, without being limited to the local maxima that appear at the intervals of ⅙ of the power supply cycle.

To reduce the output of the inverter 5, the drive signal generation unit 7a generates drive signals that reduce output current of the inverter 5, namely, the current in the motor 6. Alternatively, to reduce the output of the inverter 5, the drive signal generation unit 7a generates drive signals that decrease a frequency of the output voltage of the inverter 5, namely rotational speed of the motor 6.

In the presence of the voltage imbalance, the output voltage of the converter 2a fluctuates over a wider range, increasing a maximum instantaneous value of the current to result in overcurrent. However, the power conversion apparatus 100b according to the third embodiment reduces the output of the inverter 5, thereby reducing the current flowing from the converter 2a to the inverter 5; therefore, the power conversion apparatus 100b can prevent its constituent elements from being damaged by the overcurrent.

### Fourth Embodiment

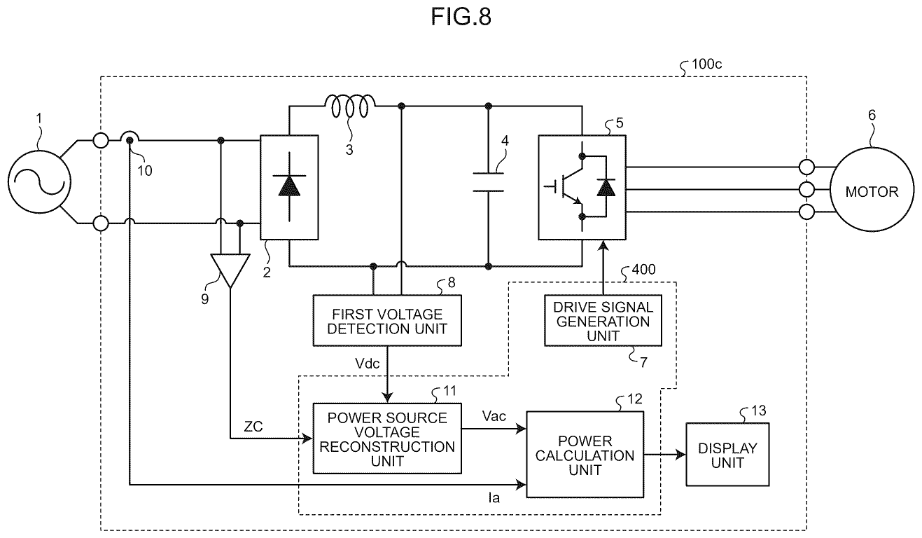

FIG. 8 is a diagram illustrating a configuration of a power conversion apparatus according to a fourth embodiment. The power conversion apparatus 100c according to the fourth embodiment differs from the power conversion apparatus 100 according to the first embodiment in that the power conversion apparatus 100c includes a display unit 13 that displays an index value correlated with power on the basis of a calculated value of the power calculation unit 12.

The display unit 13 displays the index value correlated with the input power on the basis of the calculated value of the power calculation unit 12. The display unit 13 may be a monitor incorporated into the power conversion apparatus 100c. The display unit 13 may be a personal computer or another terminal that performs operation and state monitoring of the power conversion apparatus 100c via wired communication with the power conversion apparatus 100c. The display unit 13 may be a remote controller or a portable terminal that performs the operation and the state monitoring of the power conversion apparatus 100c via wireless communication with the power conversion apparatus 100c.

Examples of the index value correlated with the power include the instantaneous power, which is sequentially calculated by the power calculation unit 12 while the motor 6 is driven, and a cumulative power value that is obtained by sequentially adding the calculated power, also including indices that are calculated using power information, such as an electricity rate conversion value (described later) and an annual performance factor (APF), which is a well-known index for air conditioners. For any values that change over time, an averaged value obtained by averaging over a predetermined period may be displayed.

The power conversion apparatus 100c according to the fourth embodiment displays the index value correlated with the power, thus allowing a user to determine an appropriate balance between a function currently performed by an apparatus incorporating the power conversion apparatus 100c, such as an air conditioner, and the index value correlated with the power and provide feedback on operation of the apparatus.

### Fifth Embodiment

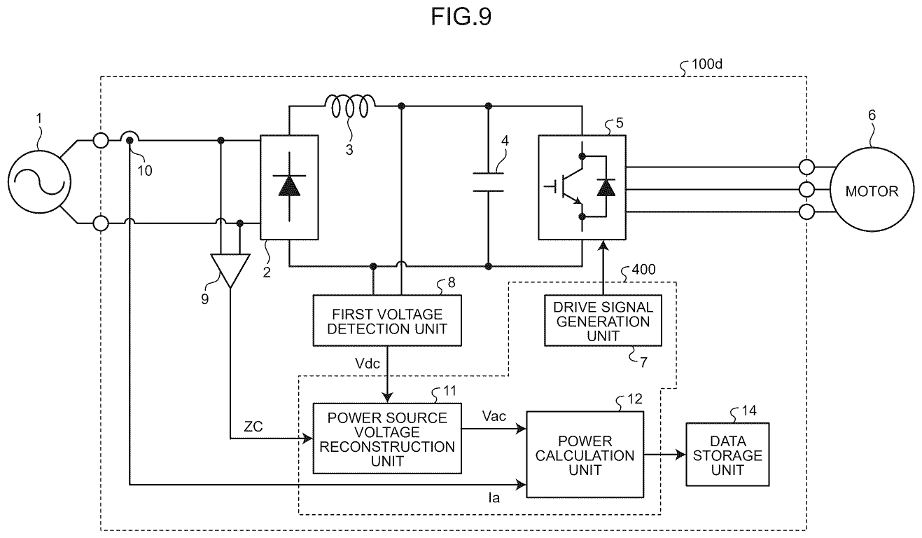

FIG. 9 is a diagram illustrating a configuration of a power conversion apparatus according to a fifth embodiment. The power conversion apparatus 100d according to the fifth embodiment differs from the power conversion apparatus 100 according to the first embodiment in that the power conversion apparatus 100d includes a data storage unit 14 that stores and retains an index value correlated with power on the basis of a calculated value of the power calculation unit 12.

Among index values that are correlated with the power and which are calculated on the basis of the calculated value of the power calculation unit 12, some index values, such as instantaneous power consumed during operation, can be sequentially calculated and updated; however, some other indices need to be calculated using a history of past drive conditions for the motor 6 and a history of power consumption over a specified period. For example, an electricity rate conversion value calculated for a fixed period on the basis of the history of power consumption and an annual performance factor of an air conditioner are among the index values that need to be calculated using the history of power consumption over the specified period.

The data storage unit 14 stores the history of past drive conditions for the motor 6 and the history of power, which are required for calculating the index values correlated with the power. The data storage unit 14 can be implemented using a memory function of a microcontroller. The memory function of the microcontroller that implements the data storage unit 14 may be included in the same microcontroller that implements the above-described functions of the drive signal generation unit 7, the power source voltage reconstruction unit 11, and the power calculation unit 12 or in a microcontroller different from the microcontroller that implements the above-described functions of the drive signal generation unit 7, the power source voltage reconstruction unit 11, and the power calculation unit 12.

The power conversion apparatus 100d according to the fifth embodiment is capable of calculating the index value that is correlated with the power and which is calculated on the basis of the history of power consumption, such as the electricity rate conversion value for the fixed period, and, therefore, can provide a user with the useful power-related information.

### Sixth Embodiment

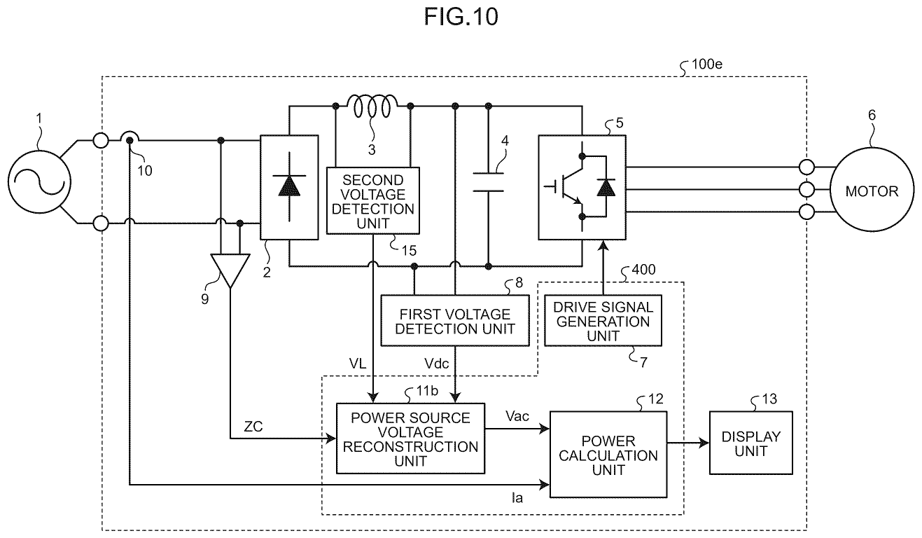

FIG. 10 is a diagram illustrating a configuration of a power conversion apparatus according to a sixth embodiment. The power conversion apparatus 100e according to the sixth embodiment differs from the power conversion apparatus 100 according to the first embodiment in that the power conversion apparatus 100e includes a second voltage detection unit 15 that detects voltage across the reactor 3.

A power source voltage reconstruction unit 11b reconstructs information related to the alternating-current quantities of the power source voltage on the basis of the voltage zero-crossing point detected by the zero-crossing detection unit 9, the voltage detection value detected by the first voltage detection unit 8, and a voltage detection value detected by the second voltage detection unit 15.

The first embodiment is based on the assumption that the voltage drop in the reactor 3 is small. However, when the reactor 3 used has a larger capacity as a countermeasure against power source harmonics, magnitude of a direct-current component of the voltage drop that occurs in the reactor 3 primarily due to coil resistance can no longer be ignored. As a result, reconstruction accuracy of the power source voltage reconstruction unit 11b will be affected. Therefore, to take the voltage drop in the reactor 3 into account in power calculation, the power conversion apparatus 100e according to the sixth embodiment includes the second voltage detection unit 15 that detects the voltage VL across the reactor 3.

In the amplitude reconstruction, the power conversion apparatus 100 according to the first embodiment determines the amplitude Vamp of the power source voltage from the voltage Vdc detected by the first voltage detection unit 8. However, the power conversion apparatus 100e according to the sixth embodiment determines the amplitude Vamp of the power source voltage on the basis of a value obtained by adding a direct-current component of the voltage VL across the reactor 3 to the voltage Vdc detected by the first voltage detection unit 8, taking into account the magnitude of the direct-current component of the voltage drop due to the coil resistance. A new current detection means (not illustrated) may be provided to detect the current flowing through the reactor 3, and power generated in the reactor 3 may be calculated on the basis of the current and the voltage VL across the reactor 3. Input power may then be the sum of the previously described power calculated by the power calculation unit 12 and the power generated in the reactor 3.

To implement the second voltage detection unit 15, a sensor or a similar device that detects the power source voltage needs to be used. However, since the voltage across the reactor 3 is smaller than the power source voltage, a small and low-cost sensor can be used compared to a detection means that detects the power source voltage.

The power conversion apparatus 100e according to the sixth embodiment also takes into account the voltage drop that occurs in the reactor 3 when reconstructing the information related to the alternating-current quantities of the power source voltage. Therefore, the alternating-current quantities are reconstructed with improved accuracy, which in turn improves accuracy of input power calculation.

### Seventh Embodiment

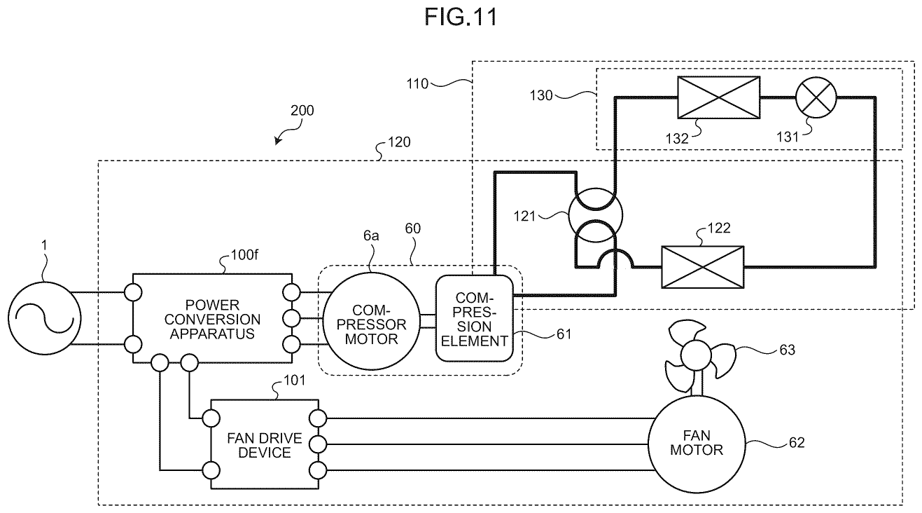

FIG. 11 is a diagram illustrating a configuration of an outdoor unit of an air conditioner according to a seventh embodiment. The air conditioner 200 according to the seventh embodiment includes the outdoor unit 120 and an indoor unit 130. The outdoor unit 120 includes a power conversion apparatus 100f; a compressor 60 that uses a motor as a drive source; a fan 63; a fan motor 62 that serves as a drive source for the fan 63; a fan drive device 101 that controls the fan 63; and a four-way valve 121 and a heat-source-side heat exchanger 122 that are part of a refrigeration cycle 110. The compressor 60 includes the compressor motor 6a and a compression element 61. The indoor unit 130 includes an expansion device 131 and a load-side heat exchanger 132 that are part of the refrigeration cycle 110.

The compressor motor 6a corresponds to the motor 6 illustrated in FIG. 1. The refrigeration cycle 110 is not necessarily limited to the illustrated configuration and may be any other known configuration.

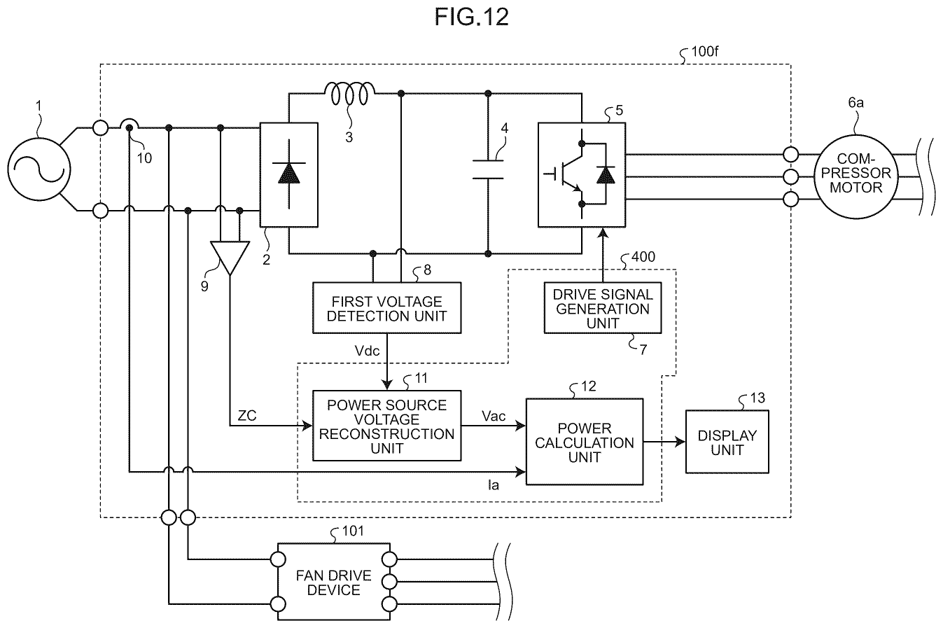

FIG. 12 is a diagram illustrating a configuration of the power conversion apparatus included in the outdoor unit of the air conditioner according to the seventh embodiment. As illustrated in FIG. 12, the power conversion apparatus 100f has the current detection unit 10 closer to the alternating-current power source 1 than branches to the compressor 60 and the fan drive device 101 are, allowing the current detection unit 10 to detect the sum of currents flowing to the compressor 60 and the fan drive device 101 to ensure inclusion of power used for driving the fan 63 in the power calculated by the power calculation unit 12.

The power conversion apparatus 100f according to the seventh embodiment can be implemented in a smaller size and at a lower cost than a power conversion apparatus configured to directly detect the power source voltage by means of a power source voltage sensor. Therefore, the outdoor unit 120, which includes the power conversion apparatus 100f, can also be implemented in a smaller size and at a lower cost.

The power conversion apparatus 100f may be provided with the display unit 13 described in the fourth embodiment. The display unit 13 may be provided in the air conditioner 200.

The above configurations illustrated in the embodiments are illustrative of the content, can be combined with other techniques that are publicly known, and can be partly omitted or changed without departing from the gist.

1. A power conversion apparatus comprising:
a converter to rectify alternating-current power supplied from an alternating-current power source;
a main-circuit capacitor to smooth the power rectified by the converter;
a reactor provided between the converter and the main-circuit capacitor;
an inverter to convert the power rectified by the converter into alternating-current power for output to a motor;
drive signal generation circuitry to generate drive signals for driving the motor, and output the drive signals to the inverter;
a first voltage detector to detect voltage at an input part of the inverter;
a zero-crossing detector to detect at least one voltage zero-crossing point on power lines interconnecting the alternating-current power source and the converter;
a current detector to detect a current value of alternating-current power supplied from the alternating-current power source;
power source voltage reconstruction circuitry to reconstruct information on a basis of the voltage zero-crossing point detected by the zero-crossing detection unit and the voltage detected at the input part of the inverter by the first voltage detection unit, the information being related to alternating-current quantities of alternating-current power supplied from the alternating-current power source; and
power calculation circuitry to calculate input power from the alternating-current power source on a basis of the information related to the alternating-current quantities and reconstructed by the power source voltage reconstruction circuitry and the current value of the alternating-current power detected by the current detector.

2. The power conversion apparatus according to claim 1, wherein the alternating-current power source is a three-phase alternating-current power source.

3. The power conversion apparatus according to claim 2, wherein
the power source voltage reconstruction circuitry notifies the drive signal generation unit of occurrence of a voltage imbalance among phases of three-phase alternating current, and
when the power source voltage reconstruction circuitry notifies the drive signal generation unit of the occurrence of the voltage imbalance among the phases of the three-phase alternating current, the drive signal generation circuitry outputs to the inverter the drive signals to reduce output power of the inverter.

4. The power conversion apparatus according to claim 1, comprising
a display unit to display information, wherein
the power calculation circuitry calculates an index value correlated with the input power and causes the display unit to display the calculated index value.

5. The power conversion apparatus according to claim 1, comprising
a data memory to store the input power calculated by the power calculation unit, wherein
the power calculation circuitry calculates an index value correlated with the input power, on a basis of historical data on the input power stored in the data memory.

6. The power conversion apparatus according to claim 1, comprising a second voltage detector to detect voltage across the reactor.

7. An outdoor unit of an air conditioner, the outdoor unit comprising the power conversion apparatus according to claim 1.

8. An outdoor unit of an air conditioner, the outdoor unit comprising the power conversion apparatus according to claim 2.

9. An outdoor unit of an air conditioner, the outdoor unit comprising the power conversion apparatus according to claim 3.

10. An outdoor unit of an air conditioner, the outdoor unit comprising the power conversion apparatus according to claim 4.

11. An outdoor unit of an air conditioner, the outdoor unit comprising the power conversion apparatus according to claim 5.

12. An outdoor unit of an air conditioner, the outdoor unit comprising the power conversion apparatus according to claim 6.
